(19) United States
(12) Patent Application Publication
(10) Pub. No.: US 2024/0354472 A1
(43) Pub. Date: Oct. 24, 2024

(54) Production Method and System for Battery Stores

(71) Applicant: Siemens Aktiengesellschaft, München (DE)

(72) Inventors: Manfred Baldauf, Erlangen (DE); Jonas Witt, Nürnberg (DE); Thomas Runkler, München (DE); Marc Christian Weber, München (DE); Clemens Otte, München (DE); Frank Steinbacher, Eckental (DE); Arno Arzberger, Stegaurach (DE); Gunnar Stoelben, Fürth (DE)

(73) Assignee: Siemens Aktiengesellschaft, München (DE)

(21) Appl. No.: 18/294,801

(22) PCT Filed: Jun. 20, 2022
(86) PCT No.: PCT/EP2022/066716

§ 371 Date: Feb. 2, 2024

(30) Foreign Application Priority Data
Aug. 5, 2021 (EP) 21189912.5

(51) Int. Cl. G06F 30/27; H01M 4/04; H01M 4/1393; H01M 4/1395

(52) U.S. Cl. CPC G06F 30/27; H01M 4/1393; H01M 4/1395; H01M 4/0419; H01M 4/0435

(57) ABSTRACT

Various embodiments of the teachings herein include a method for producing an electrode layer of a battery store by a system using an electrode layer paste. An example method includes: acquiring system parameters associated with the production of the electrode layer; acquiring a measured value of a variable of the electrode layer; calculating a correction value from a comparison of the acquired measured value of the electrode layer with a defined target value range; and setting the system parameters as a function of the calculated correction value.

### CROSS-REFERENCE TO RELATED APPLICATIONS

This application is a U.S. National Stage Application of International Application No. PCT/EP2022/066716 filed Jun. 20, 2022, which designates the United States of America, and claims priority to EP application Ser. No. 21/189,912.5 filed Aug. 5, 2021, the contents of which are hereby incorporated by reference in their entirety.

### TECHNICAL FIELD

The present disclosure relates batteries. Various embodiments of the teachings herein include systems and/or methods for producing an electrode layer of a battery store.

### BACKGROUND

Lithium-ion accumulators, herein also called lithium-ion batteries, are used, due to their high power and energy density, as energy stores in mobile and static applications. A lithium-ion battery typically comprises a number of battery cells. A battery cell, in particular a lithium-ion battery cell, comprises a plurality of layers. These layers typically comprise anodes, cathodes, separators, and further elements. These layers can be designed as stacks or as windings.

The electrodes typically comprise metal foils, in particular comprising copper and/or aluminum, which are coated with an active material. Here a paste containing lithium compounds or carbon, known as slurry, is typically applied as the active material. The foils and the coating have in each case a thickness of a few dozen micrometers. A variation of just a few micrometers in the thickness of the coating, the porosity or the material composition has negative effects on the quality of the electrode.

Disadvantageously, with an irregular coating, lower quality battery cells are therefore produced. Furthermore, safe operation of the battery cell is not ensured.

Detecting different fault patterns (e.g. contaminations, formation of air bubbles) online in the coating process remains a challenge. In some cases, they only become obvious once the entire production process of the battery cell has concluded, within the scope of what is known as an end-of-line test. In some cases, defective coatings are also only ascertained after the battery cell has been in operation for several years. A large proportion of rejected defective battery cells is therefore generated during battery production. The production process therefore has a large material requirement and energy requirement in order to produce a sufficient number of high-quality battery cells.

### SUMMARY

The teachings of the present disclosure provide methods and systems for producing an electrode layer of a battery store and a production system for producing an electrode layer of a battery store, which allow quick and direct intervention in the production process and thus reduce the reject rate in battery production. For include a method for producing an example, some embodiments electrode layer of a battery store by means of at least one system, in which an electrode layer paste is used, comprising: acquiring system parameters of at least one system associated with the production of the electrode layer, acquiring one or more measured values of a measured variable of the electrode layer paste and/or the electrode layer, calculating/determining a correction value from a comparison of the acquired measured value of the electrode layer with a defined target value range and setting the system parameters as a function of the calculated correction value.

In some embodiments, a material comprising lithium and/or carbon is used as the electrode layer paste.

In some embodiments, when the one or more measured values is acquired one or more surface features, a layer thickness, a gradient of the layer thickness, a porosity of the layer thickness and/or one or more spatial inhomogeneities of the electrical conductance are acquired.

In some embodiments, the method further comprises: comparing the one or more measured values with defined error clusters, selecting the relevant error cluster and setting the system parameters with the aid of a correction value defined for the error cluster.

In some embodiments, the method further comprises creating correction models, which map the relationship between measured values of different measured variables and system parameters.

In some embodiments, a supervised or unsupervised machine learning method creates the correction models in combination with knowledge-based models and/or physical models.

In some embodiments, the machine learning method uses neural networks, deep-learning methods, cluster methods or physically informed neural networks.

In some embodiments, the system parameters are set by means of a feedback loop.

In some embodiments, an adjustment of the correction models is carried out iteratively in situ by the effect of the feedback loop on the measured values.

In some embodiments, a soft sensor carries out the steps: acquiring the one or more measured values of a measured variable, determining the correction value and setting the system parameters.

In some embodiments, the method further comprises acquiring the changes to the measured values of different measured variables after setting the system parameters with the aid of the correction value.

As another example, some embodiments include a production system for producing an electrode layer of a battery store, embodied to carry out one or more of the methods as described herein.

### BRIEF DESCRIPTION OF THE DRAWINGS

The teachings of the present disclosure are described and explained in more detail below with the aid of the exemplary embodiment illustrated in the FIGURE. In the exemplary embodiment and the FIGURE, the same or similarly acting elements can each be provided with the same reference characters. The elements shown and their size relationships to one another should not generally be seen as true to scale; instead, individual elements may be shown with proportionately larger dimensions for improved representation and/or understanding.

### DETAILED DESCRIPTION

Various embodiments of the teachings herein may be applied to the production of an electrode layer of a battery store in at least one system using an electrode layer paste. An example method comprises acquiring system parameters of the system which are associated with the production of the electrode layer. Further, one or more measured values of at least two measured variables of the electrode layer paste and/or the electrode layer is/are acquired. Furthermore, a correction value is determined from a comparison of the acquired measured values of the electrode layer with a defined target value range for the measured variables. The system parameters are set as a function of the determined correction value.

As another example, some embodiments include a system for producing an electrode layer of a battery store embodied to carry out the one or more of the methods described herein. In the disclosure, a system is understood to mean in particular a facility in which one or more of the following processes takes place:
production, processing, and/or conveying the electrode layer paste,
coating the electrode with the electrode layer paste,
drying the coating, and/or
calendering the electrode layer.

Electrode layer paste (slurry) is understood to mean the raw substance for the production of the electrode layer, which is applied to the electrodes.

One or more parameters which can be set in the system are to be understood as system parameters. In particular, influenceable environmental influences are also to be understood as system parameters. System parameters include for instance:
mass flow of the electrode layer paste,
roller speed of the rollers during calendering
properties of the nozzles, in particular deposits and/or blockages,
temperature, in particular fluctuations in the temperature e.g. of the electrode layer paste,
viscosity of the electrode layer paste, and/or
contaminations in particular of the electrode layer paste, for instance from the environment.

The measured variable relates to the electrode layer paste and/or to the electrode layer generated from the electrode layer paste as a function of the process step examined in each case. Measured variables of the electrode layer paste are for instance temperature, viscosity, particle size distribution, degree of dispersion, contaminations from the environment, or the like. Measured variables of the electrode layer are for instance the surface topology and defects, porosity, composition or path conductance of the electrode layer, in which the measured values are determined in eddy current measurements, for instance.

The correction value means one or more change/s in the system parameters, in order to achieve a desired change in the properties of the electrode layer paste or the electrode layer in the further production process. In some embodiments, the correction value is determined by a comparison of the measured values with defined target value and error value ranges, wherein in the case of measured variables outside of the target value range for the error value ranges, specific correction values are defined in each case.

In some embodiments, the electrode layer paste comprises a material which contains lithium. Lithium, in particular the materials containing lithium which are used in lithium-ion batteries comprise a particularly high energy density.

In some embodiments, the values of the following variables may be measured:
one or more surface features such as the appearance of agglomerates, recesses and/or holes, scratches, frayed edges and/or rough areas,
layer thickness, in particular temporal fluctuations in the layer thickness and/or spatial gradients of the layer thickness,
porosity of the layer thickness, in particular spatial and/or temporal fluctuations in the porosity, and/or
one or more spatial inhomogeneities of the electrical conductance, in particular spatial and/or temporal fluctuations in the inhomogeneity of the electrical conductance.

In some embodiments, the following additionally take place:
comparing the one or more measured values with defined error clusters,
selecting the error cluster, and
setting the system parameters with the aid of a correction value defined for the error cluster.

An error cluster means a grouping of surface phenomena, e.g. combinations of measured values, lying outside of the target value range, of one or more measured variables. In particular, the combination of several abnormal measured variables with measured values outside of a defined target value range may be an error cluster, which matches a current situation in the system. One or more system parameters can be adjusted with the aid of a correction value, wherein the correction value is defined for the respective error cluster. The correction value can comprise a number of individual single correction values, which affect different system parameters. In some embodiments, the correction value is transferred by way of control signals to a system controller in order to adjust the system parameters.

In some embodiments, the method comprises the creation of correction models, which map the relationship between measured values of different measured variables, in particular with measured values outside of a target value range, and system parameters. Correction models can be created on the basis of laboratory examinations, for instance, which map the relationship between measured variables, in particular surface features, or between error clusters and the causative physical causes of error. These models can be used in what are known as soft sensors, in order to determine the correction values required for the causative system parameters from variables which can be measured in the production system. In some embodiments, these relationships and correction values are contained in the correction models in order to retrieve the target values in the further course of the production process.

In some embodiments, a supervised or an unsupervised machine learning method in combination with knowledge-based models and/or physical models creates the correction models. As a result, advantageously the obtained knowledge, from laboratory examinations and the ongoing operation of the system, about the relationships between the correction values and the effects on the measured variables can be analyzed and the correction models can be adjusted.

In some embodiments, the machine learning method uses neural networks, deep-learning methods, cluster methods or physically informed neural networks in order to adjust the correction models. The correction models created in this way or as described above by means of laboratory examinations can also be used as what are known as soft sensors in ongoing production lines in the system like real sensors, although the effects to be determined are only derived indirectly from other measured variables and system parameters.

In some embodiments, the system parameters are set continuously during operation of the system by means of a feedback loop.

In some embodiments, the correction models are adjusted in situ and iteratively by the effects of the changes performed in the feedback loop by implementing the correction value being analyzed and being used in a machine learning method in combination with knowledge-based models for the improvement of the correction models or correction values.

In some embodiments, a soft sensor takes over the steps of acquiring the one or more measured values of a measured variable, determining the correction value and setting the system parameters.

In some embodiments, the changes to the measured values of different measured variables are tracked subsequent to setting the system parameters with the aid of the correction value.

Some embodiments include a production system for producing an electrode layer of a battery store, which is designed so that it is embodied to carry out one or more of the methods as described herein.

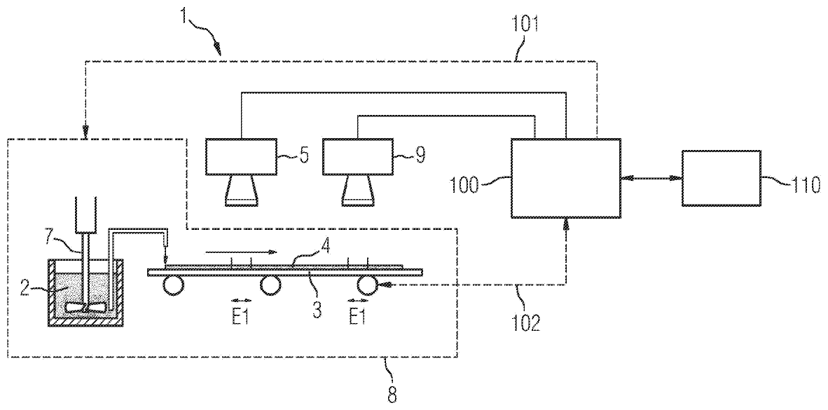

FIG. 1 shows a production system 1. The production system 1 comprises an electrode layer production facility 8. The electrode layer production facility 8 comprises two measuring facilities: a laser scan facility 5 as a first measuring facility 5, a porosity measuring facility as a second measuring facility 9. Both measuring facilities are connected to a computing unit 100 by way of data cables.

The electrode layer production facility 8 comprises a carrier substrate 3, to which an electrode layer 4 comprising an electrode layer paste 2 (slurry) is applied. The electrode layer paste 2 is homogenized in a container by means of a stirring apparatus 7. The stirring apparatus 7 and the substrate transport are likewise connected to the computing unit 100 by way of a data cable.

In this example, at least one image of the electrode layer 4 and an item of location information μl is recorded as a measured variable with the laser scan facility 5. Furthermore, a second measured variable, namely a porosity and/or an electrode layer thickness of the electrode layer 4, is determined by means of the porosity measuring facility 9. In this example, the analysis takes place at the same point on the electrode layer 4, once the substrate with the electrode layer 4 has been further transported, now characterized with the item of location information E1′. The porosity is analyzed during the production of the electrode layer 4. The porosity measuring facility is designed in particular as an ultrasound measuring unit, as an x-ray absorption unit or as a computed tomography unit.

The measured values determined by the porosity measuring facility 9 (first measured variable) and laser scan facility 5 (second measured variable) are transmitted in this example to the computing unit 100. In the computing unit 100, the measured values, here the topological properties, of the electrode layer 4 are determined on the basis of at least one image of the laser scan facility 5 as a function of the item of location information E1. A comparison of the transmitted values with target value ranges defined in each case for the respective measured variables takes place in the computing unit 100.

Correction models which have been determined on the basis of laboratory examinations and map the relationship between surface features or clusters of features and the in particular physical causes of error are stored in a storage unit 110. Furthermore, the correction models comprise correction values for system parameters of the production system, which can eliminate the causes of error during operation of the system. Examples of correction values could affect the viscosity or the temperature of the electrode layer paste, the conveying velocity of the electrode layer paste, particle size distribution, dispersion of the particles in the slurry, the roller speed of the electrode foils (substrate), state and setting of coating nozzles and slots, their gap dimension, etc.

The computing unit 100 transfers the correction values to the controller of the electrode layer production facility 8, so that the system parameters are adjusted during ongoing operation of the production system 1.

The correction models created in this way are also known as soft sensors because they can be used like real sensors in ongoing production lines although the effects to be determined are only derived indirectly from other measured variables and control variables.

The magnitude of the correction value can either be taught from measurement data or iteratively adjusted in situ by the effect of a feedback loop. The use of an AI engine for adjusting, improving and training the correction models is suitable here. The AI unit is connected to the computing unit 100 by means of a data line. Here the AI unit is connected to the data transferred by the laser scan facility 5 and the porosity measuring facility 9 and to the first control signals 101 and second control signals 102 transferred to the electrode layer production facility 8 by means of the control signal 101. In other exemplary embodiments, the AI unit could be connected to optical cameras in combination with image processing methods, hyperspectral cameras and/or eddy current measuring facilities.

The AI unit therefore evaluates the effects of the correction models continuously and during ongoing operation of the production system 1 improves the correction models stored in the storage unit 110.

Although the teachings of the present disclosure have been illustrated and described in detail by the exemplary embodiment, the scope of the disclosure is not restricted by the examples disclosed. Variations thereof can be derived by a person skilled in the art without departing from the protective scope thereof.

### LIST OF REFERENCE CHARACTERS

1 System
2 Electrode layer paste (slurry)
3 Carrier substrate
4 Electrode layer
5 Laser scan facility
7 Stirring apparatus
8 Electrode layer production facility
9 Porosity measuring facility
100 Computing unit
101 First control signal
102 Second control signal
110 Storage unit

What is claimed is:

1. A method for producing an electrode layer of a battery store by a system using an electrode layer paste, the method comprising:
acquiring system parameters associated with production of the electrode layer;
acquiring a measured values of a variable of the electrode layer;
calculating a correction value from a comparison of the acquired measured value of the electrode layer with a defined target value range; and
setting the system parameters as a function of the calculated correction value.

2. The method as claimed in claim 1, wherein the electrode layer paste comprises lithium and/or carbon.

3. The method as claimed in claim 1, wherein the variable comprises one or more characteristics select from a group ng of:
one or more surface features,
a layer thickness,
a gradient of the layer thickness,
a porosity of the layer thickness, and/or
one or more spatial inhomogeneities of the electrical conductance are acquired.

4. The method as claimed in claim 1, further comprising:
comparing the one or more measured values with defined error clusters;
selecting the relevant error cluster; and
setting the system parameters with the aid of a correction value defined for the error cluster.

5. The method as claimed in claim 1, further comprising
creating correction models to map the relationship between measured values of different measured variables and system parameters.

6. The method as claimed in claim 1, wherein a machine learning method creates the correction models in combination with knowledge-based models and/or physical models.

7. The method as claimed in claim 6, wherein the machine learning method uses neural networks, deep-learning methods, cluster methods or physically informed neural networks.

8. The method as claimed in claim 1, further comprising setting the system parameters using a feedback loop.

9. The method as claimed in claim 8, wherein adjusting the correction models is carried out iteratively in situ by the effect of the feedback loop on the measured values.

10. The method as claimed in claim 1, further comprising using a soft sensor to acquire the one or more measured values of a measured variable, determine the correction value, and set the system parameters.

11. The method as claimed in claim 1, further comprising
acquiring the changes to the measured values of different measured variables after setting the system parameters with the aid of the correction value.

12. (canceled)
